(19) United States
(12) Patent Application Publication
(10) Pub. No.: US 2002/0196009 A1
(43) Pub. Date: Dec. 26, 2002

(54) Measuring method and sensor apparatus measuring chemicals in pharmaceutical analysis and synthesis

(76) Inventor: Dieter Sewald, Au (CH)

Correspondence Address: LERNER AND GREENBERG, P.A., Post Office Box 2480, Hollywood, FL, 33022-2480, US

(21) Appl. No.: 10/200,634

(22) Filed: Jul. 22, 2002

Related U.S. Application Data
(63) Continuation of application No. PCT/EP01/00581, filed on Jan. 19, 2001.

(30) Foreign Application Priority Data
Jan. 21, 2000 (DE) 100 02 595.1

(51) Int. Cl. G01R 23/00; G01R 23/08

(52) U.S. Cl. 324/76.51

(57) ABSTRACT

A measuring method and a sensor device measure chemicals in pharmaceutical analysis and synthesis. According to the method, the course of a reaction is detected by a change of frequency of a high frequency oscillator. The sensor device includes a measuring cell in which the reaction takes place, said measuring cell forming part of a resonator of an HF-oscillator.

### CROSS-REFERENCE TO RELATED APPLICATION:

This application is a continuation of copending International Application No. PCT/EP01/00581, filed Jan. 19, 2001, which designated the United States and was not published in English.

### BACKGROUND OF THE INVENTION

1. Field of the Invention:

The present invention relates to a measuring method and a sensor apparatus for chemical or pharmaceutical analysis and synthesis.

In the chemical and pharmaceutical industry, increasing interest has focused on the bioelectronics sector, in which synergy between organic analysis and electronic measurement technology appears possible. Here, one concrete object is not, as hitherto, to look for valuable substances and active materials by using strategic synthesis to create usable substances according to a tactical procedure from an initially incomprehensible number of possible reactions between different molecules because such a strategy is generally very time-consuming. On the “trial & error” principle, as many as possible numerous combinations of molecules for potential reaction mechanisms are investigated. Rather, a preferred approach yields conclusions in the shortest possible time as to whether molecule A has reacted with molecule B, how high the yield of the reaction is, or simply only whether a substance includes only molecule A or molecule B.

For a long time, therefore, a search has been made for bioelectronic interfaces with which the course of a reaction over time can be registered via the action on an electrical variable such as current flow or voltage.

The classical route in this sector of industry was previously a deliberate search for a specific active substance. Well-trained staff attempted from their level of knowledge to synthesize substances with the desired characteristics via a selection of potential reaction partners and then to analyze the reaction products.

Because such a procedure requires a very great deal of time until it is successful, and, therefore, every possibility cannot be covered, there is an interest to change to automated methods. Against this background, firstly suitable bioelectronic interface structures are being researched, and secondly fundamental questions are also being raised as to a suitable measuring technique.

In this regard, FIG. 1 represents an overview of known electrical analytical methods. The methods proposed apply principles of electronic measuring technology and are based on the evaluation of classical electronic variables. For this purpose, for example, the time course of a reaction over time is to be registered via the change in a current, the voltage, an impedance or a capacitance.

Here, in every case the sensitivity of the measuring system is in principle a problem, that is to say the action of the chemical biological reaction on the variable to be measured is generally very low. For example, changes in a current flow in the nA range have to be registered. In addition, the limited dynamic range of such a measurement is also closely associated with this. If, for example, it were wished to register the course of a reaction via a capacitance change, the change can move with the order of magnitude of the parasitic capacitances of an electrode configuration. As soon as the latter dominate, a bioelectronic measurement is no longer possible.

### SUMMARY OF THE INVENTION

It is accordingly an object of the invention to provide a measuring method and sensor apparatus measuring chemicals in pharmaceutical analysis and synthesis that overcome the hereinafore-mentioned disadvantages of the heretofore-known devices of this general type and that specify a measuring method and a sensor apparatus for chemical or pharmaceutical analysis which exhibits a significantly higher sensitivity. According to the invention, this object is achieved by the course of a reaction being detected by using the frequency change of a high-frequency oscillator.

With the foregoing and other objects in view, there is provided, in accordance with the invention, a method for measuring chemicals for pharmaceutical analysis and synthesis. The method includes detecting a course of a reaction by detecting a frequency change of a high-frequency (HF) oscillator.

With the objects of the invention in view, there is also provided a sensor apparatus for measuring chemicals for pharmaceutical analysis and synthesis. The apparatus includes a high-frequency (HF) oscillator having a measuring cell in which a reaction proceeds.

In this case, it is preferred for the reaction to proceed in a measuring cell provided with electrodes, and for this measuring cell to be used as part of the resonator of an HF oscillator.

In this case, by evaluating the oscillation frequency of the HF oscillator over the course of a reaction over time, characteristic information about the progress of this reaction is obtained.

The frequency change is preferably measured for various known organic substances and stored and, by comparing the frequency change when measuring an unknown sample with the stored frequency changes, information about the identity of this sample is obtained.

Here, it is particularly preferred to determine the frequency change in the same reaction or in the same sample by starting from different basic frequencies, because in this way considerably more information about the reaction or the sample can be obtained with only slightly greater effort.

Here, it is particularly preferred to use part of the oscillator signal for determining the oscillation frequency via a control path. It is particularly preferred to convert the high-frequency signal by using a mixer circuit into a lower frequency range, in order to simplify the further processing of the signal.

The frequency can then be determined, for example, by using a frequency-voltage converter or frequency counter.

Likewise, the frequency can be determined by using spectral transformation.

In this case, the spectral transformation preferably can be carried out by using a digital signal processor or microprocessor.

In particular for applications in genetic engineering, a measuring method is preferred in which some bases of long identical DNA or RNA individual strands are applied to an inner surface of the measuring cell, so that the impedance and therefore the resonance of the measuring cell changes if DNA or RNA with a suitable individual strand end is present in the sample introduced into the measuring cell, because this individual strand end then hybridizes with the individual strands.

The spacing of the electrodes should be chosen to be less than 1 μm, preferably of the order of magnitude of 0.2 μm.

Here, it is particularly preferred for all the high-frequency components for the individual cells to be disposed on an integrated circuit. In this way, optimum miniaturization can be achieved.

Appropriate integrated circuits can preferably be fabricated using CMOS technology.

The object according to the invention is likewise achieved by a sensor apparatus for chemical or pharmaceutical analysis in which a measuring cell is provided in which a reaction proceeds and the measuring cell forms part of a resonator of an HF oscillator.

Here, it is particularly preferred for the HF oscillator to be adjustable to various basic frequencies. As a result, substantially more information can be obtained during the measurement.

A control path is preferably connected to the HF oscillator, and is connected to a mixer circuit. In this way, the frequency of the signal to be processed further can be reduced into a frequency range which is substantially easier to process.

A frequency-voltage converter, a frequency counter or a device for spectral transformation is preferably connected to the mixer circuit.

The device used for the spectral transformation can be, for example, a digital signal processor or a microprocessor.

The apparatus according to the invention can preferably include a large number of measuring cells, which are integrated microelectronically on a chip. In this way, a large number of samples can be measured simultaneously or a large number of measurements can be carried out simultaneously. The chip is preferably constructed using CMOS technology, because analog high-frequency circuits for this application can easily be implemented using this technology.

For use in genetic engineering, it is particularly preferred for some bases of long identical DNA or RNA individual strands to be applied to an inner surface of the measuring cell, so that the impedance and therefore the resonance of the measuring cell changes if DNA or RNA with a suitable individual strand end is present in the sample introduced into the measuring cell.

The spacing of the electrodes is preferably less than 1 μm, even better of the order of magnitude of 0.2 μm.

The boundary conditions linked to the subject permit a great potential application to be supposed for a microelectronic solution. In order to be able to perform automated analysis in the large industrial style and in the shortest possible time, the invention teaches integrating a large number of measuring cells, including the corresponding electronic circuits, microelectronically on silicon. Such a measuring cell substantially includes a container, which can be filled with organic test substances. Disposed in this container is a suitable electrode structure as a bioelectronic interface. The construction of the integrated electronic circuit depends on the selected measurement method.

Other features that are considered as characteristic for the invention are set forth in the appended claims.

Although the invention is illustrated and described herein as embodied in a measuring method and sensor apparatus measuring chemicals in pharmaceutical analysis and synthesis, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows an overview of the electroanalytical methods according to the prior art;

FIG. 2 is a partial diagrammatic and partial schematic view showing various embodiments of the sensor apparatus according to the invention;

FIG. 3 is a partial diagrammatic and partial schematic diagram showing an equivalent circuit for the electrode structure;

FIG. 4 is a graph plotting amplitude versus frequency to show the measured signal in the course of a molecular reaction;

FIG. 5 is a graph plotting amplitude versus frequency showing the course of the measured signal for various molecules;

FIG. 6 is a partial diagrammatic and partial schematic view showing a microelectronically integrated measuring cell according to the invention;

FIG. 7 shows a method according to the invention for electronic detection of hybridization;

FIG. 8 shows an impedance spectroscopic method for detection of hybridization, the sensor apparatus being shown before the hybridization; and

FIG. 9 shows the apparatus from FIG. 8 after the hybridization.

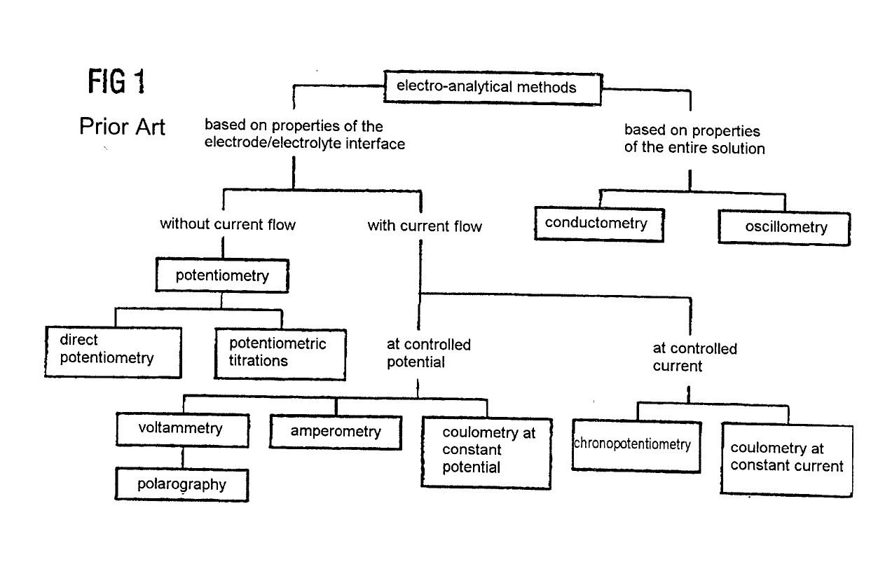

### DESCRIPTION OF THE PREFERRED EMBODIMENTS

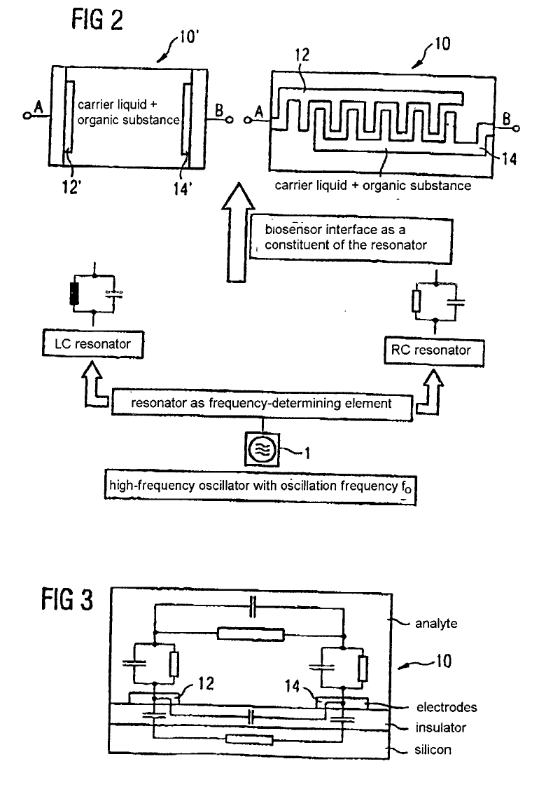

Referring now to the figures of the drawings in detail and first, particularly to FIG. 2 thereof, there is shown, as a possible method according to the invention for analyzing a biochemical process, the shift in the frequency over the course of the process over time will be evaluated.

A high-frequency oscillator 1 oscillates at a known frequency f₀. Its oscillation frequency is defined in every case by a frequency-determining element (resonator), which is constructed in conventional discrete circuit technology as an LC or RC type.

The construction of a biochemical measuring cell 10 may now be described by an electronic equivalent circuit, as shown by way of example in a simple form in FIG. 3. The topology and dimensioning of the discrete elements of such an electronic equivalent circuit is reliably dependent on the selected electrode structure (for example interdigital electrodes, MOS transistor) and on the analyte that is to be examined. In this case, the size of specific circuit elements is defined, since they are given by the geometric construction of the measuring cell 10. Others will change their values in the course of a biochemical reaction of the analyte.

Instead of the direct evaluation of changing variables such as R and C, the measuring cell 10 at the electrode connections 12, 14 can preferably be used as part of the resonator of an HF oscillator 1. If specific electronic equivalent circuit elements change during a reaction, this leads to a shift in the oscillation frequency of the oscillator 1. Even very small changes can effect relatively large detuning of the frequency. By evaluating the oscillation frequency in the course of a reaction over time, characteristic information about a reaction sequence can then be obtained.

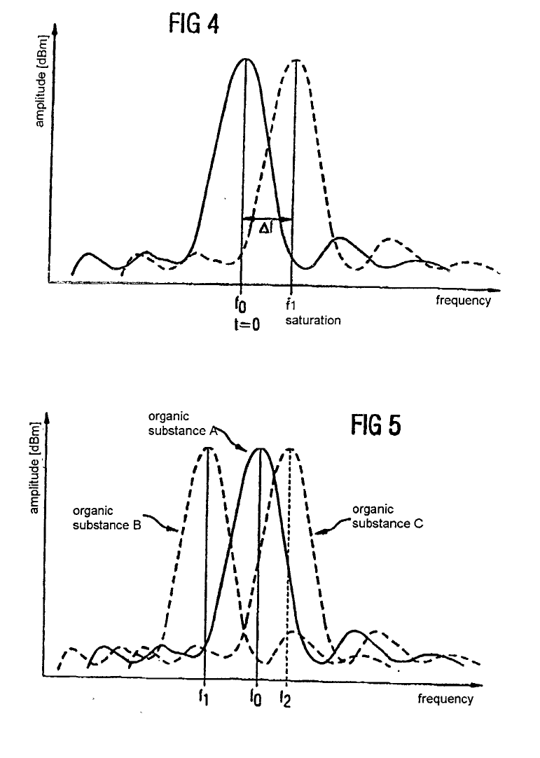

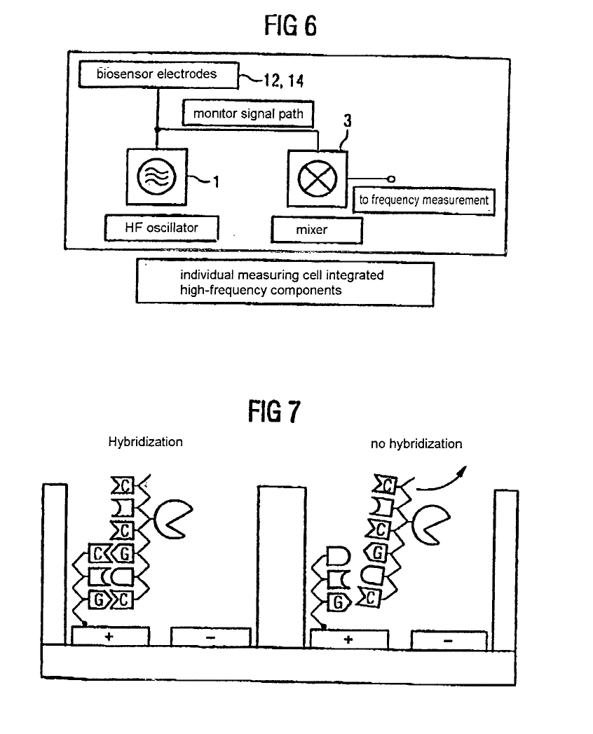

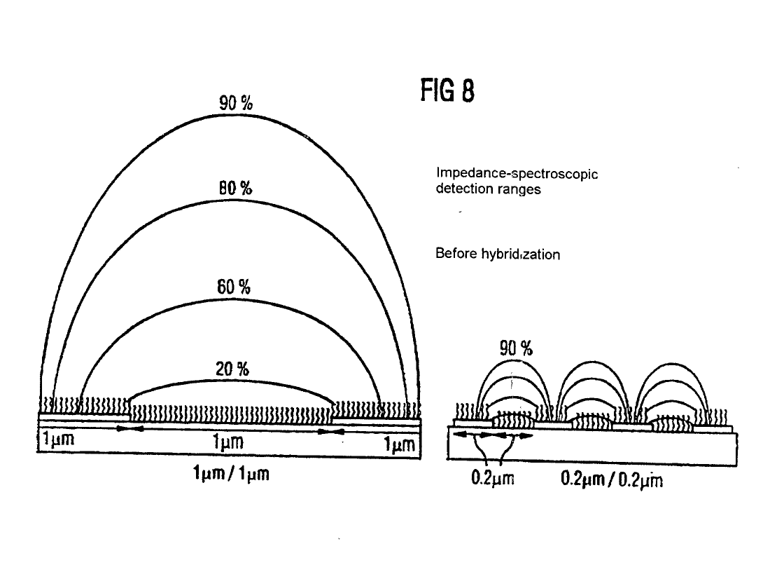

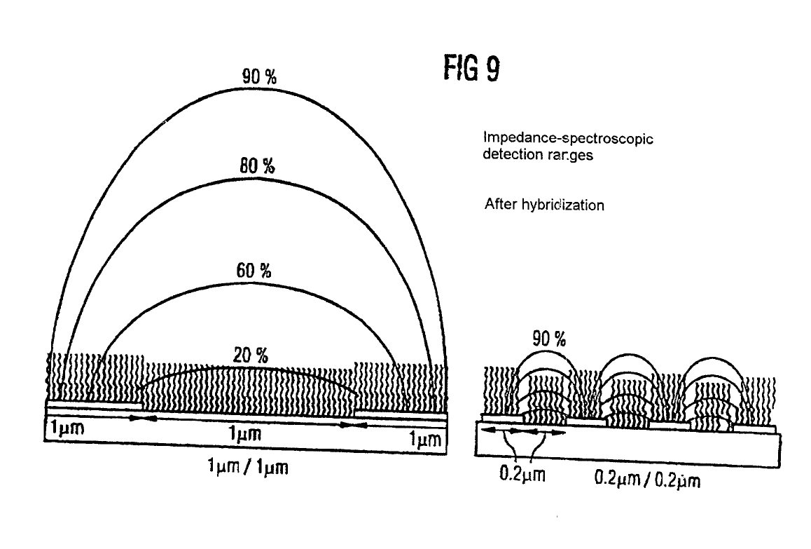

A conceivable measurement scenario is shown in FIG. 4. Here, it is assumed that there are two reactants (molecule A and molecule B) in a measuring cell 10.

At the time t=0, no reaction has yet taken place, the HF oscillator 1 oscillates at a frequency f₀. In the course of the reaction, the resonance of the measuring cell 10 and therefore the oscillator frequency shifts to f₁, until ultimately a saturated state occurs. Statements about the yield of the reaction or whether a reaction has taken place at all are then possible via the level of the frequency shift. This is because if no frequency change results at all, it is to be recorded that no reaction has taken place.

In addition, if the oscillator resonance frequencies for various organic substances are known, it is possible to identify individual unknown samples within one measuring cycle.

By applying high-frequency measurement techniques, level differences over several orders of magnitude can be registered. A correspondingly high dynamic range is to be expected. The quality of such a measurement is limited substantially by the achievable quality of the resonator, which is also determined by the construction of the measuring cell 10 and the analyte.

The duration of a biochemical reaction is in most cases orders of magnitude greater than the time needed for a measuring cycle (the latter lies in the ms range). The obvious thing is, therefore, to carry out a large number of measurements on the various samples in parallel.

According to the invention, for the application in biosensing, for example chemical or pharmaceutical analysis, a measuring principle is proposed which is novel in this connection. The method is based on the evaluation of the frequency change of a high-frequency oscillator 1 as a function of the course of a (biochemical) reaction and is well suited to microelectronic implementation. As compared with the known methods, this type of measurement technology permits better results with respect to sensitivity and dynamic range to be expected.

The measuring method according to the invention can initially be implemented as a microelectronically integrated solution, irrespective of the selection of a specific technology.

The requirement for a high integration density with low costs, and the fact that analog high-frequency circuits are accommodated “on chip” signifies little expenditure and easy handling of the measurement technology. A fixed frequency oscillator 1 whose oscillation frequency is concomitantly determined by the electrical characteristics of a biosensor electrode 2 is needed. Via a control path, part of the oscillator signal is used to determine the oscillation frequency. In order to permit simple evaluation, the high-frequency signal is converted to a lower frequency range by a mixer circuit 3. At this point, the frequency can be determined with a frequency-voltage converter, frequency counter or via spectral transformation (DSP, microprocessor), depending on how accurately or intelligently such a measuring system is to operate.

It is conceivable to integrate a large number of such individual units microelectronically in order to be able to carry out measurements on an industrial scale.

I claim:

1. A method for measuring chemicals in pharmaceutical analysis and synthesis, which comprises detecting a course of a reaction by detecting a frequency change of a high-frequency (HF) oscillator.

2. The method according to claim 1, which further comprises:
providing a measuring cell with electrodes; and
using the measuring cell as part of a resonator of the HF oscillator.

3. The method according to claim 1, which further comprises obtaining information about the course of the reaction by evaluating an oscillation frequency of the HF oscillator throughout the course of the reaction.

4. The measuring method according to claim 1, which further comprises:
measuring and storing frequency changes for various known organic substances; and
identifying a sample by comparing a frequency change of the sample with the stored frequency changes.

5. The method according to claim 1, which further comprises determining the frequency change of the reaction by starting from different basic frequencies in one sample.

6. The method according to claim 1, which further comprises using part of a high-frequency signal of the high-frequency oscillator to determine an oscillation frequency via a control path.

7. The method according to claim 6, which further comprises converting the high-frequency signal to a lower frequency range by using a mixer circuit.

8. The method according to claim 6, which further comprises uses a frequency-voltage converter for the determining of the oscillation frequency.

9. The method according to claim 6, which further comprises using a frequency counter for the determining of the oscillation frequency.

10. The method according to claim 6, which further comprises using spectral transformation for the determining of the oscillation frequency.

11. The method according to claim 10, which further comprises using a digital signal processor for carrying out the spectral transformation.

12. The method according to claim 10, which further comprises using a microprocessor for carrying out the spectral transformation.

13. The method according to claim 2, which further comprises:
applying some bases of individual strands of genetic material to an inner surface of the measuring cell, the genetic material being selected from the group consisting of DNA and RNA;
measuring changes in an impedance and therefore a resonance of the measuring cell when complementary genetic material hybridizes with the genetic material.

14. The measuring method according to claim 13, which further comprises spacing the electrodes less than 1 μm apart from each other.

15. The measuring method according to claim 14, which further comprises spacing the electrodes less than 0.2 μm apart from each other.

16. The method according to claim 1, which further comprises disposing the high-frequency oscillator on an integrated circuit.

17. The measuring method according to claim 16, which further comprises fabricating the integrated circuit using CMOS technology.

18. A sensor apparatus for measuring chemicals in pharmaceutical analysis and synthesis, comprising a high-frequency (HF) oscillator having a measuring cell in which a reaction proceeds.

19. The apparatus according to claim 18, wherein said HF oscillator is adjustable to different basic frequencies.

20. The apparatus according to claim 18, further comprising:
a mixer circuit; and
a control path connected to said HF oscillator and said mixer circuit.

21. The apparatus according to claim 20, further comprising a device for determining an oscillation frequency connected to said mixer circuit, said device for determining the oscillation frequency being selected from the group consisting of a frequency-voltage converter, a frequency counter, and a device for spectral transformation.

22. The apparatus according to claim 21, wherein said device for spectral transformation is a digital signal processor.

23. The apparatus according to claim 21, wherein said device for spectral transformation is a microprocessor.

24. The apparatus according to claim 18, which further comprises:
at least one further measuring cell; and
a chip microelectronically integrating said measuring cells.

25. The apparatus according to claim 25, which further comprises a large number of said measuring cells integrated microelectronically on said chip.

26. The apparatus according to claim 24, wherein said chip is constructed using CMOS technology.

27. The apparatus according to claim 18, wherein:
said measuring cell has an inner surface; and
some bases of individual strands of genetic material are applied to said inner surface of said measuring cell, said genetic material being selected from the group consisting of DNA and RNA, said bases being able to hybridize with complementary genetic material, and an impedance and therefore a resonance of said measuring cell changing when said complementary genetic material hybridizes with said genetic material.

28. The apparatus according to claim 18, further comprising electrodes disposed in said measuring cell and spaced less than 1 μm apart from each other.

29. The apparatus according to claim 28, wherein said electrodes are spaced less than 0.2 μm apart from each other.
